(19) United States
(12) Patent Application Publication
(10) Pub. No.: US 2026/0025111 A1
(43) Pub. Date: Jan. 22, 2026

(54) TRANSISTOR-CASCADED CIRCUIT

(71) Applicant: Realtek Semiconductor Corp., HsinChu (TW)

(72) Inventor: Shih-Hsiung Huang, HsinChu (TW)

(73) Assignee: Realtek Semiconductor Corp., HsinChu (TW)

(21) Appl. No.: 19/242,970

(22) Filed: Jun. 19, 2025

(30) Foreign Application Priority Data
Jul. 16, 2024 (TW) 113126565

(51) Int. Cl. H03F 3/04; H03K 19/0175

(52) U.S. Cl. CPC H03F 3/04; H03K 19/017509

(57) ABSTRACT

A transistor-cascaded circuit is provided. The transistor-cascaded circuit includes a first transistor, a second transistor, a level shifter and an alternating current (AC) signal enhancement circuit. The level shifter is configured to receive a first input signal of a pair of differential input signals and shift the first input signal to a shifted bias voltage level, in order to generate a shifted input signal to at least one of a gate terminal of the first transistor and a gate terminal of the second transistor. In addition, the AC signal enhancement circuit is configured to enhance an AC signal of the shifted input signal according to a voltage difference between the first input signal and a second input signal of the pair of differential input signals. More particularly, one of the first transistor and the second transistor is an N-type transistor, and the other one is a P-type transistor.

### BACKGROUND OF THE INVENTION

### 1. Field of the Invention

The present invention is related to amplifiers and source followers, and more particularly, to a transistor-cascaded circuit (e.g. an inverter-type amplifier or an inverter-type source follower).

### 2. Description of the Prior Art

An input stage of an amplifier operating at a low supply voltage may be implemented with multiple transistors in order to increase a transconductance value. Optimum operating points of these transistors may be at different bias voltage levels, however. In order to ensure performance of an entire circuit, a related art method adjusts a bias voltage level of an input signal through a level shifter, which enables the transistors at the input stage of the amplifier to operate at optimal bias voltage levels. As these transistors typically have parasitic capacitors, however, this results in attenuation of the input signal during a process of adjusting the bias voltage level, thereby reducing overall bandwidth and performance of the amplifier.

Thus, there is a need for a novel architecture, which can solve the problem mentioned above without introducing any side effect or in a way that is less likely to introduce side effects.

### SUMMARY OF THE INVENTION

An objective of the present invention is to provide a transistor-cascaded circuit (e.g. an inverter-type amplifier or an inverter-type source follower), which can enhance magnitude of an input signal or reduce the attenuation of the input signal during the process of adjusting the bias voltage level without greatly increasing costs.

At least one embodiment of the present invention provides a transistor-cascaded circuit. The transistor-cascaded circuit comprises a first transistor, a second transistor, a level shifter and an alternating current (AC) signal enhancement circuit, wherein the second transistor is coupled to the first transistor, the level shifter is coupled to a gate terminal of the first transistor and a gate terminal of the second transistor, and the AC signal enhancement circuit is coupled to the gate terminal of the first transistor and the gate terminal of the second transistor. The level shifter is configured to receive a first input signal of a pair of differential input signals and shift an original bias voltage level of the first input signal to a shifted bias voltage level, in order to generate a shifted input signal to at least one of the gate terminal of the first transistor and the gate terminal of the second transistor. In addition, the AC signal enhancement circuit is configured to enhance an AC signal of the shifted input signal according to a voltage difference between the first input signal and a second input signal of the pair of differential input signals. More particularly, one of the first transistor and the second transistor is an N-type transistor, and the other one of the first transistor and the second transistor is a P-type transistor.

The transistor-cascaded circuit provided by the embodiment of the present invention can utilize the AC signal enhancement circuit to compensate attenuation of an AC signal of an input signal, to ensure overall performance of the transistor-cascaded circuit. In addition, the embodiment of the present invention will not greatly increase additional costs. Thus, the present invention can solve the problem of the related art without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an inverter-type amplifier according to an embodiment of the present invention.

FIG. 2 is a diagram illustrating a source follower according to an embodiment of the present invention.

FIG. 3 is a diagram illustrating level shifters according to an embodiment of the present invention.

FIG. 4 is a diagram illustrating level shifters according to another embodiment of the present invention.

FIG. 5 is a diagram illustrating a partial circuit of a source follower according to an embodiment of the present invention.

FIG. 6 is a diagram illustrating a partial circuit of a source follower according to another embodiment of the present invention.

### DETAILED DESCRIPTION

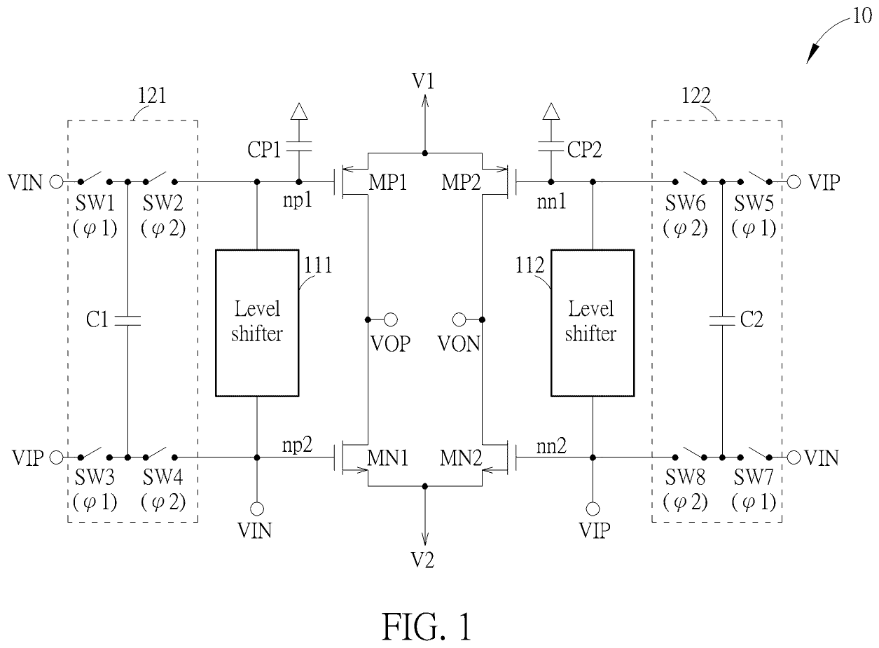

FIG. 1 is a diagram illustrating a transistor-cascaded circuit such as an inverter-type amplifier 10 according to an embodiment of the present invention. As shown in FIG. 1, the inverter-type amplifier 10 may comprise a first transistor such as transistors MP1 and MP2, a second transistor such as transistors MN1 and MN2, level shifters 111 and 112 (e.g. direct current (DC) level shifting circuits), and alternating current (AC) signal enhancement circuits 121 and 122. In this embodiment, the transistor MN1 is coupled to the transistor MP1, the level shifter 111 is coupled to a gate terminal of the transistor MP1 (e.g. a node np1 shown in FIG. 1) and a gate terminal of the transistor MN1 (e.g. a node np2 shown in FIG. 1), and the AC signal enhancement circuit 121 is coupled to the gate terminal of the transistor MP1 and the gate terminal of the transistor MN1. In addition, the transistor MN2 is coupled to the transistor MP2, the level shifter 112 is coupled to a gate terminal of the transistor MP2 (e.g. a node nn1 shown in FIG. 1) and a gate terminal of the transistor MN2 (e.g. a node nn2 shown in FIG. 1), and the AC signal enhancement circuit 122 is coupled to the gate terminal of the transistor MP2 and the gate terminal of the transistor MN2. As the inverter-type amplifier 10 is a differential circuit, a left-side of the inverter-type amplifier 10 and a right-side thereof have symmetric architectures and operations. For brevity, the following paragraphs describe based on the left-side of the inverter-type amplifier 10 only, and the rest may be deduced by analogy. The level shifter 111 is configured to receive a first input signal of a pair of differential input signals, such as a signal VIN, and shift an original bias voltage level of the signal VIN to a shifted bias voltage level to generate a shifted input signal to at least one of the gate terminal of the transistor MP1 and the gate terminal of the transistor MN1. In addition, the AC signal enhancement circuit 121 is configured to enhance an AC signal of the shifted input signal according to a voltage difference between the signal VIN and a second input signal of the pair of differential input signals, such as a signal VIP. In this embodiment, the transistors MP1 and MP2 are P-type transistors, and the transistors MN1 and MN2 are N-type transistors. It should be noted that the transistors MP1 and MP2 are coupled to a node V1, where the node V1 is coupled to a reference voltage source (e.g. a supply voltage source VDDH) or a supply current source (e.g. a supply current source coupled between the supply voltage source VDDH and the node V1). Similarly, the transistors MN1 and MN2 are coupled to a node V2, where the node V2 is coupled to a reference voltage source (e.g. a supply voltage source VSSN) or a supply current source (e.g. a supply current source coupled between the node V2 and the supply voltage source VSSN). In this embodiment, a voltage level of the supply voltage source VDDH may be higher than a voltage level of the supply voltage source VSSN, but the present invention is not limited thereto.

In this embodiment, the gate terminal of the transistor MP1 is configured to receive the shifted input signal, and the gate terminal of the transistor MN1 is configured to receive the signal VIN. More particularly, the level shifter 111 may receive the signal VIN via the node np2 coupled to the gate terminal of the transistor MN1 and shift the original bias voltage level of the signal VIN (e.g. a bias voltage level suitable for the transistor MN1) to a bias voltage level suitable for the transistor MP1, in order to generate the shifted input signal on the node np1 coupled to the gate terminal of the transistor MP1. As a result, the transistors MP1/MP2 and the transistors MN1/MN2 can operate at suitable bias voltage levels, respectively, to generate a pair of differential output signals such as signals {VOP, VON}. As the gate terminals of the transistors MP1 and MP2 (e.g. the nodes np1 and nn1) respectively have parasitic capacitors CP1 and CP2, the present invention utilizes the AC signal enhancement circuits 121 and 122 to enhance AC signals on the nodes np1 and nn1.

In this embodiment, the AC signal enhancement circuit 121 may comprise a capacitor C1, where the capacitor C1 is configured to sample the voltage difference between the signals VIN and VIP. More particularly, in a first phase of a control clock (e.g. a phase (1), a first end of the capacitor C1 (e.g. an upper end of the capacitor C1 shown in FIG. 1) is configured to receive the signal VIN, and a second end of the capacitor C1 (e.g. a lower end of the capacitor C1 shown in FIG. 1) is configured to receive the signal VIP. In a second phase of the control clock (e.g. a phase 2), the first end of the capacitor C1 is coupled to the gate terminal of the transistor MP1 (e.g. coupled to the node np1), and the second end of the capacitor C1 is coupled to the gate terminal of the transistor MN1 (e.g. coupled to the node np2). In particular, the AC signal enhancement circuit 121 further comprises switches SW1, SW2, SW3 and SW4, where the switch SW1 is coupled to the first end of the capacitor C1 and is configured to receive the signal VIN, the switch SW2 is coupled between the first end of the capacitor C1 and the gate terminal of the transistor MP1 (e.g. the node np1), the switch SW3 is coupled between the second end of the capacitor C1 and is configured to receive the signal VIP, and the switch SW4 is coupled between the second end of the capacitor C1 and the gate terminal of the transistor MN1 (e.g. the node np2). In the first phase of the control clock, the switches SW1 and SW3 are turned on (e.g. conductive) (labeled “SW1 (φ1)” and “SW3 (φ1)” in FIG. 1 for better comprehension) and the switches SW2 and SW4 are turned off (e.g. disconnected), to make the voltage difference between the signals VIN and VIP be sampled on the capacitor C1. In the second phase of the control clock, the switches SW1 and SW3 are turned off and the switches SW2 and SW4 are turned on (labeled “SW2 (φ2)” and “SW4 (42)” in FIG. 1 for better comprehension), to make the AC signal of the shifted input signal on the gate terminal of the transistor MP1 be enhanced according to the voltage difference on the capacitor C1. Operations of a capacitor C2, and switches SW5, SW6, SW7 and SW8 within the AC signal enhancement circuit 122 may be deduced by analogy, and related details are omitted here for brevity.

In some embodiments, the inverter-type amplifier 10 may utilize a control signal generator to generate two non-overlapping control signals according to the control clock, where the two non-overlapping control signals may represent the phases q1 and 42, respectively, but the present invention is not limited thereto.

It should be noted that the original bias voltage levels of the signal VIN and VIP in the embodiment of FIG. 1 are the bias voltage levels suitable for the transistor MN1 (e.g. a common mode voltage of the signals VIN and VIP which is at an optimum operating level of the transistor MN1), but the present invention is not limited thereto. In some embodiments, the original bias voltage levels of the signal VIN and VIP are the bias voltage levels suitable for the transistor MP1 (e.g. the common mode voltage of the signals VIN and VIP which is at an optimum operating level of the transistor MP1). Under this condition, the level shifter 111 may receive the signal VIN via the node np1 coupled to the gate terminal of the transistor MP1 and shift the original bias voltage level of the signal VIN (e.g. the bias voltage level suitable for the transistor MP1) to the bias voltage level suitable for the transistor MN1, to generate the shifted input signal on the node np2 coupled to the gate terminal of the transistor MN1, where the switch SW1 is configured to receive the signal VIN and the switch SW3 is configured to receive the signal VIP, to ensure that a polarity of the voltage difference on the capacitor C1 is able to be utilized for enhancing the AC signal of the shifted input signal.

In this embodiment, the transistors MP1 and MP2 are P-type transistors, and the transistors MN1 and MN2 are N-type transistors, where a drain terminal of the transistor MP1 is coupled to a drain terminal of the transistor MN1, and a drain terminal of the transistor MP2 is coupled to a drain terminal of the transistor MN2.

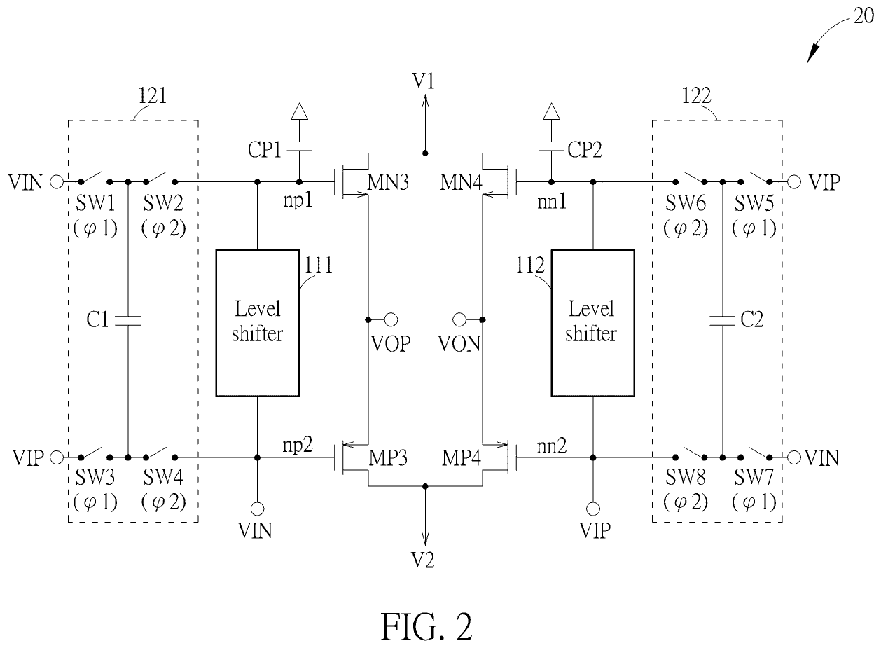

FIG. 2 is a diagram illustrating a transistor-cascaded circuit such as a source follower 20 according to an embodiment of the present invention. In comparison with the inverter-type amplifier 10 shown in FIG. 1, the transistors MP1, MP2, MN1 and MN2 are replaced with transistors MN3, MN4, MP3 and MP4, respectively, where the remaining circuits are the same as those detailed in FIG. 1. More particularly, the transistors MN and MN4 are N-type transistors, and the transistors MP3 and MP4 are P-type transistors, where a source terminal of the transistor MN3 is coupled to a source terminal of the transistor MP3, and a source terminal of the transistor MN4 is coupled to a source terminal of the transistor MP4.

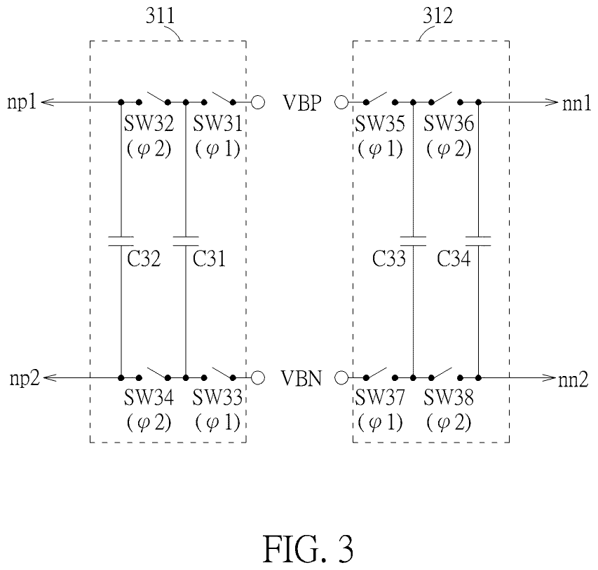

FIG. 3 is a diagram illustrating level shifters 311 and 312 according to an embodiment of the present invention, where the level shifter 311 and 312 may be examples of the level shifters 111 and 112 shown in FIG. 1 and FIG. 2, respectively. For brevity, the following descriptions are based on the inverter-type amplifier 10 shown in FIG. 1, and implementation of the level shifters 311 and 312 in the source follower 20 shown in FIG. 2 may be deduced by analogy. As shown in FIG. 3, the level shifter 311 may comprise capacitors C31 and C32 and switches SW31, SW32, SW33 and SW34, where the capacitor C32 is coupled between the gate terminal of the transistor MP1 (e.g. the node np1) and the gate terminal of the transistor MN1 (e.g. the node np2). In addition, in the first phase of the control clock, the switches SW31 and SW33 are turned on (labeled “SW31 (φ1)” and “SW33 (φ1)” in FIG. 3 for better comprehension) and the switches SW32 and SW34 are turned off, to make the capacitor C31 be coupled between a first bias voltage source such as a bias voltage source VBP and a second bias voltage source such as a bias voltage source VBN, where the bias voltage source VBP is configured to provide the bias voltage level suitable for the transistors MP1 and MP2, and the bias voltage source VBN is configured to provide the bias voltage level suitable for the transistors MN1 and MN2. In the second phase of the control clock, the switches SW31 and SW33 are turned off and the switches SW32 and SW34 are turned on (labeled “SW32 (φ2)” and “SW34 (φ2)” in FIG. 3 for better comprehension), to make the capacitor C31 be coupled between the gate terminal of the transistor MP1 (e.g. the node np1) and the gate terminal of the transistor MN1 (e.g. the node np2). Operations of the level shifter 312 (e.g. the capacitors C33 and C34 and the switches SW35, SW36, SW37 and SW38 therein) coupled to the nodes nn1 and nn2 may be deduced by analogy, and related details are omitted here for brevity.

Under a condition without implementation of the AC signal enhancement circuit 121, magnitude of the AC signal on the node np1 may be attenuated due to a charge sharing effect of the capacitors C31, C32 and CP1. Assuming that both capacitances of the capacitors C31 and C32 are 2×C and a capacitance of the parasitic capacitor CP1 is 1×C, when the signal VIN=Vcm−dV and the signal VIP=Vcm+dV (e.g. Vom represents the common mode voltage of the signals VIN and VIP, and dV represents an AC signal of the signals VIN and VIP), the magnitude of the AC signal on the node np1 may be attenuated to ((4/5)×dV). By comparison, under a condition with implementation of the AC signal enhancement circuit 121, as the capacitor C1 may sample the voltage difference between the signals VIN and VIP (i.e. the AC signal of the signal VIN and VIP), signal attenuation caused by the charge sharing effect mentioned above can be compensated. Assuming that all capacitances of the capacitors C1, C31 and C32 are 2×C and the capacitance of the parasitic capacitor CP1 is 1×C, when the signal VIN=Vcm−dV and the signal VIP=Vcm+dV, the magnitude of the AC signal on the node np1 is ((5/4)×dV). Thus, the AC signal enhancement circuit 121 can effectively prevent the AC signal on the node np1 from being attenuated. Effects of the AC signal enhancement circuit 122 may be deduced by analogy, and related details are omitted here for brevity.

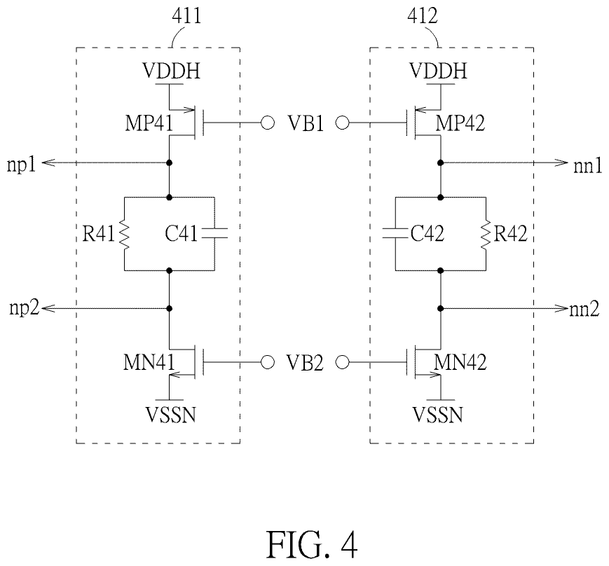

FIG. 4 is a diagram illustrating level shifters 411 and 412 according to another embodiment of the present invention, where the level shifters 411 and 412 may be examples of the level shifters 111 and 112 shown in FIG. 1 and FIG. 2, respectively. For brevity, the following descriptions are based on the inverter-type amplifier 10 shown in FIG. 1, and implementation of the level shifters 411 and 412 in the source follower 20 shown in FIG. 2 may be deduced by analogy. As shown in FIG. 4, the level shifter 411 may comprise a capacitor C41, a resistor R41, a first current source such as a transistor MP41 controlled by a bias voltage VB1, and a second current source such as a transistor MN41 controlled by a bias voltage VB2. The capacitor C41 is coupled between the gate terminal of the transistor MP1 (e.g. the node np1) and the gate terminal of the transistor MN1 (e.g. the node np2), and the resistor R41 is coupled between the gate terminal of the transistor MP1 (e.g. the node np1) and the gate terminal of the transistor MN1 (e.g. the node np2). In addition, the transistor MP41 is coupled between a first reference voltage source such as the supply voltage source VDDH and the gate terminal of the transistor MP1 (e.g. the node np1), and the transistor MN41 is coupled between a second reference voltage source such as the supply voltage source VSSN and the gate terminal of the transistor MN1 (e.g. the node np2). Thus, a voltage difference generated by a current of the transistor MP41 and MN41 flowing through the resistor R41 may represent a shifting amount applied to the signal VIN by the level shifter 411, and the capacitor C41 may transmit the AC signal of the signal VIN. In some embodiments, the transistor MP41 or MN41 may be implemented with multiple transistors coupled in series, but the present invention is not limited thereto. In addition, operations of the level shifter 412 (e.g. the capacitor C42, the resistor R42, and the transistors MP42 and MN42 therein) coupled to the nodes nn1 and nn2 may be deduced by analogy, and related details are omitted here for brevity.

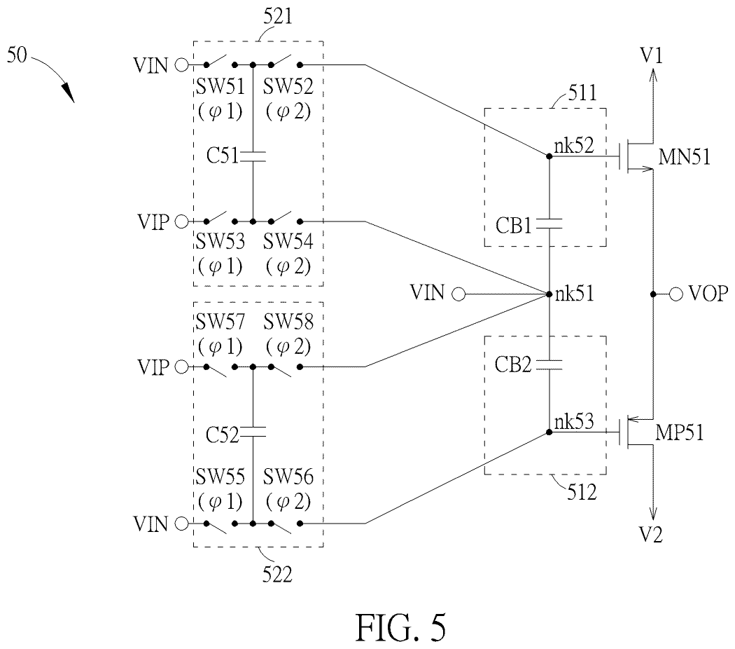

FIG. 5 is a diagram illustrating a partial circuit (e.g. a left-side half circuit) of a source follower 50 according to an embodiment of the present invention. As shown in FIG. 5, the source follower 50 may comprise transistors MN51 and MP51, level shifters 511 and 512, and AC signal enhancement circuits 521 and 522. In some embodiments, each of the level shifters 511 and 512 may be implemented by the level shifter 311 shown in FIG. 3. For example, when the level shifter 511 is implemented by the level shifter 311, a capacitor CB1 shown in FIG. 5 may represent the capacitor C32 within the level shifter 311. When the level shifter 512 is implemented by the level shifter 311, a capacitor CB2 shown in FIG. 5 may represent the capacitor C32 within the level shifter 311. In some embodiments, each of the level shifters 511 and 512 may be implemented by the level shifter 411 shown in FIG. 4. For example, when the level shifter 511 is implemented by the level shifter 411, the capacitor CB1 shown in FIG. 5 may represent the capacitor C41 within the level shifter 411. When the level shifter 512 is implemented by the level shifter 411, the capacitor CB2 shown in FIG. 5 may represent the capacitor C41 within the level shifter 411. For brevity, the level shifters 511 and 512 are not completely depicted in FIG. 5, where those skilled in this art should understand how to implement the level shifters in this embodiment with the architecture of the level shifter 311 or 411 according to connecting positions of the capacitor CB1 and CB2 depicted in FIG. 5, and related details are omitted here for brevity.

In this embodiment, the level shifter 511 (e.g. the capacitor CB1 therein) is coupled between a middle node such as a node nk51 and a gate terminal of the transistor MN51 (e.g. a node nk52 shown in FIG. 5), and the level shifter 512 (e.g. the capacitor CB2 therein) is coupled between the middle node such as the node nk51 and a gate terminal of the transistor MP51 (e.g. a node nk53 shown in FIG. 5). The level shifter 511 is configured to receive the signal VIN from the node nk51 and shift the original bias voltage level of the signal VIN to a first bias voltage level (e.g. a voltage level suitable for the transistor MN51) to generate a first shifted input signal to the gate terminal of the transistor MN51 (e.g. the node nk52), and the level shifter 512 is configured to receive the signal VIN from the node nk51 and shift the original bias voltage level of the signal VIN to a second bias voltage level (e.g. a voltage level suitable for the transistor MP51) to generate a second shifted input signal to the gate terminal of the transistor MP51 (e.g. the node nk53).

In this embodiment, the AC signal enhancement circuit 521 is coupled between the gate terminal of the transistor MN51 (e.g. the node nk52) and the node nk51, and the AC signal enhancement circuit 522 is coupled between the gate terminal of the transistor MP51 (e.g. the node nk53) and the node nk51. The AC signal enhancement circuit 521 is configured to enhance a first AC signal of the first shifted input signal on the gate terminal of the transistor MN51 (e.g. the node nk52) according to the voltage difference between the signals VIN and VIP, and the AC signal enhancement circuit 522 is configured to enhance a second AC signal of the second shifted input signal on the gate terminal of the transistor MP51 according to the voltage difference between the signals VIN and VIP.

As shown in FIG. 5, the AC signal enhancement circuit 521 may comprise a capacitor C51 and switches SW51, SW52, SW53 and SW54, and the AC signal enhancement circuit 522 may comprise a capacitor C52 and switches SW55, SW56, SW57 and SW58. In the first phase of the control clock, the switches SW51, SW53, SW55 and SW57 are turned on (labeled “SW51 (φ1)”, “SW53 (φ1)”, “SW55 (φ1)” and “SW57 (φ1)” in FIG. 5 for better comprehension) and the switches SW52, SW54, SW56 and SW58 are turned off, to make each of the capacitors C51 and C52 sample the voltage difference between the signals VIN and VIP. In the second phase of the control clock, the switches SW51, SW53, SW55 and SW57 are turned off and the switches SW52, SW54, SW56 and SW58 are turned on (labeled “SW52 (φ2)”, “SW54 (φ2)”, “SW56 (φ2)” and “SW58 (φ2)” in FIG. 5 for better comprehension), to make the capacitor C51 be coupled between the gate terminal of the transistor MN51 and the node nk51 and make the capacitor C52 be coupled between the gate terminal of the transistor MP51 and the node nk51, thereby enhancing the first AC signal of the first shifted input signal on the gate terminal of the transistor MN51 and the second AC signal of the second shifted input signal on the gate terminal of the transistor MP51, respectively.

In this embodiment, the transistor MN51 is an N-type transistor and the transistor MP51 is a P-type transistor. In some embodiments, the transistor MN51 may be replaced with a P-type transistor and the transistor MP51 may be replaced with an N-type transistor, to modify the source follower 50 shown in FIG. 5 to be an inverter-type amplifier.

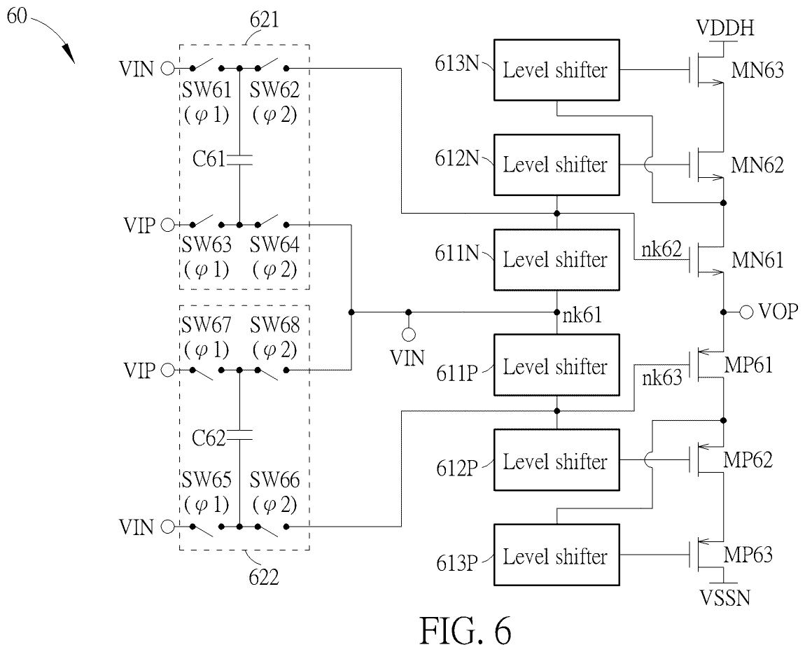

FIG. 6 is a diagram illustrating a partial circuit (e.g. a left-side half circuit) of a source follower 60 according to another embodiment of the present invention. As shown in FIG. 6, the source follower 60 may comprise transistors MN61, MN62, MN63, MP61, MP62 and MP63, the level shifters 611N, 612N, 613N, 611P, 612P and 613P, and AC signal enhancement circuits 621 and 622. In this embodiment, the level shifters 611N, 612N and 613N may respectively shift the signal VIN to bias voltage levels suitable for gate terminals of the transistor MN61, MN62 and MN63, and the level shifters 611P, 612P and 613P may respectively shift the signal VIN to bias voltage levels suitable for gate terminals of the transistor MP61, MP62 and MP63. In some embodiments, each of the level shifters 611N, 612N, 613N, 611P, 612P and 613P may be implemented with the level shifter 311 shown in FIG. 3. In some embodiments, each of the level shifters 611N, 612N, 613N, 611P, 612P and 613P may be implemented with the level shifter 411 shown in FIG. 4. Those skilled in this art should understand how to implement the level shifter 311 shown in FIG. 3 or the level shifter 411 shown in FIG. 4 in the level shifters 611N, 612N, 613N, 611P, 612P and 613P according to the architecture shown in FIG. 6, and related details are therefore omitted here for brevity.

In this embodiment, the level shifter 611N is coupled between a middle node such as the node nk61 and the gate terminal of the transistor MN61 (e.g. the node nk62 shown in FIG. 6), the level shifter 612N is coupled between an output of the level shifter 611N and the gate terminal of the transistor MN62, and the level shifter 613N is coupled between a source terminal of the transistor MN62 and the gate terminal of the transistor MN63. In addition, the level shifter 611P is coupled between the middle node such as the node nk61 and the gate terminal of the transistor MP61 (e.g. the node nk63 shown in FIG. 6), the level shifter 612P is coupled between an output of the level shifter 611P and the gate terminal of the transistor MP62, and the level shifter 613P is coupled between a source terminal of the transistor MP62 and the gate terminal of the transistor MP63. The level shifter 611N is configured to receive the signal VIN from the node nk51 and shift the original bias voltage level of the signal VIN to a first bias voltage level (e.g. a voltage level suitable for the transistor MN61) to generate a first shifted input signal to the gate terminal of the transistor MN61 (e.g. the node nk62), the level shifter 612N may shift the first shifted input signal to a voltage level suitable for the gate terminal of the transistor MN62, and the level shifter 613N may shift a signal on a source terminal of the transistor MN62 to a voltage level suitable for the gate terminal of the transistor MN63. In addition, the level shifter 611P is configured to receive the signal VIN from the node nk61 and shift the original bias voltage level of the signal VIN to a second bias voltage level (e.g. a voltage level suitable for the transistor MP61) to generate a second shifted input signal to the gate terminal of the transistor MP61 (e.g. the node nk63), the level shifter 612P may shift the second shifted input signal to a voltage level suitable for the gate terminal of the transistor MP62, and the level shifter 613P may shift a signal on a source of the transistor MP62 to a voltage level suitable for the gate terminal of the transistor MP63.

In this embodiment, the AC signal enhancement circuit 621 is coupled between the gate terminal of the transistor MN61 (e.g. the node nk62) and the node nk61, and the AC signal enhancement circuit 622 is coupled between the gate terminal of the transistor MP61 (e.g. the node nk63) and the node nk61. The AC signal enhancement circuit 621 is configured to enhance a first AC signal of the first shifted input signal on the gate terminal of the transistor MN61 (e.g. the node nk62) according to the voltage difference between the signals VIN and VIP, and the AC signal enhancement circuit 622 is configured to enhance a second AC signal of the second shifted input signal on the gate terminal of the transistor MP61 according to the voltage difference between the signals VIN and VIP.

As shown in FIG. 6, the AC signal enhancement circuit 621 may comprise a capacitor C61 and switches SW61, SW62, SW63 and SW64, and the AC signal enhancement circuit 622 may comprise a capacitor C62 and switches SW65, SW66, SW67 and SW68. In the first phase of the control clock, the switches SW61, SW63, SW65 and SW67 are turned on (labeled “SW61 (φ1)”, “SW63 (φ1)”, “SW65 (φ1)” and “SW67 (φ1)” in FIG. 6 for better comprehension) and the switches SW62, SW64, SW66 and SW68 are turned off, to make each of the capacitors C61 and C62 sample the voltage difference between the signals VIN and VIP. In the second phase of the control clock, the switches SW61, SW63, SW65 and SW67 are turned off and the switches SW62, SW64, SW66 and SW68 are turned on (labeled “SW62 (φ2)”, “SW64 (φ2)”, “SW66 (φ2)” and “SW68 (φ2)” in FIG. 6 for better comprehension), to make the capacitor C61 be coupled between the gate terminal of the transistor MN61 and the node nk61 and make the capacitor C62 be coupled between the gate terminal of the transistor MP61 and the node nk61, thereby enhancing the first AC signal of the first shifted input signal on the gate terminal of the transistor MN61 and the second AC signal of the second shifted input signal on the gate terminal of the transistor MP61, respectively.

In this embodiment, the transistors MN61, MN62 and MN63 are N-type transistors and the transistors MP61, MP62 and MP63 are P-type transistors. In some embodiments, the transistors MN61, MN62 and MN63 may be replaced with P-type transistors and the transistors MP61, MP62 and MP63 may be replaced with N-type transistors, to modify the source follower 60 shown in FIG. 6 to be an inverter-type amplifier.

To summarize, the transistor-cascaded circuit (such as an inverter-type amplifier or an inverter-type source follower) provided by the embodiments of the present invention samples an AC signal in differential signals through a capacitor, and utilizes charges on this capacitor to compensate an AC signal in a shifted input signal to solve the problem of signal attenuation, where the architecture of the present invention can be combined with various types of level shifters. In addition, the embodiments of the present invention will not greatly increase additional costs. Thus, the present invention can solve the problem of the related art without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor-cascaded circuit, comprising:
a first transistor;
a second transistor, coupled to the first transistor;
a level shifter, coupled to a gate terminal of the first transistor and a gate terminal of the second transistor, configured to receive a first input signal of a pair of differential input signals and shift an original bias voltage level of the first input signal to a shifted bias voltage level, in order to generate a shifted input signal to at least one of the gate terminal of the first transistor and the gate terminal of the second transistor; and
an alternating current (AC) signal enhancement circuit, coupled to the gate terminal of the first transistor and the gate terminal of the second transistor, configured to enhance an AC signal of the shifted input signal according to a voltage difference between the first input signal and a second input signal of the pair of differential input signals;
wherein one of the first transistor and the second transistor is an N-type transistor, and the other one of the first transistor and the second transistor is a P-type transistor.

2. The transistor-cascaded circuit of claim 1, wherein a drain terminal of the first transistor is coupled to a drain terminal of the second transistor.

3. The transistor-cascaded circuit of claim 1, wherein a source terminal of the first transistor is coupled to a source terminal of the second transistor.

4. The transistor-cascaded circuit of claim 1, wherein the gate terminal of the first transistor is configured to receive the shifted input signal, and the gate terminal of the second transistor is configured to receive the first input signal.

5. The transistor-cascaded circuit of claim 4, wherein the AC signal enhancement circuit comprises:
a capacitor, configured to sample the voltage difference between the first input signal and the second input signal;
wherein:
in a first phase of a control clock, a first end of the capacitor is configured to receive the first input signal, and a second end of the capacitor is configured to receive the second input signal; and
in a second phase of the control clock, the first end of the capacitor is coupled to the gate of the first transistor, and the second end of the capacitor is coupled to the gate of the second transistor.

6. The transistor-cascaded circuit of claim 5, wherein the AC signal enhancement circuit further comprises:
a first switch, coupled to the first end of the capacitor, configured to receive the first input signal;
a second switch, coupled between the first end of the capacitor and the gate of the first transistor;
a third switch, coupled to the second end of the capacitor, configured to receive the second input signal; and
a fourth switch, coupled between the second end of the capacitor and the gate of the second transistor;
wherein:
in the first phase of the control clock, the first switch and the third switch are turned on and the second switch and the fourth switch are turned off, to make the voltage difference between the first input signal and the second input signal be sampled on the capacitor; and
in the second phase of the control clock, the first end of the capacitor is coupled to the gate of the first transistor, and the second end of the capacitor is coupled to the gate of the second transistor.

7. The transistor-cascaded circuit of claim 1, wherein the level shifter comprises:
a first capacitor, coupled between the gate terminal of the first transistor and the gate terminal of the second transistor; and
a second capacitor, wherein:
in a first phase of a control clock, the second capacitor is coupled between a first bias voltage source and a second bias voltage source; and
in a second phase of the control clock, the second capacitor is coupled between the gate terminal of the first transistor and the gate terminal of the second transistor.

8. The transistor-cascaded circuit of claim 1, wherein the level shifter comprises:
a capacitor, coupled between the gate terminal of the first transistor and the gate terminal of the second transistor;
a resistor, coupled between the gate terminal of the first transistor and the gate terminal of the second transistor;
a first current source, coupled between a first reference voltage source and the gate terminal of the first transistor; and
a second current source, coupled between a second reference voltage source and the gate terminal of the second transistor.

9. The transistor-cascaded circuit of claim 1, wherein:
the level shifter comprises:
a first level shifter, coupled between a middle node and the gate terminal of the first transistor, configured to receive the first input signal from the middle node and shift the original bias voltage level of the first input signal to a first bias voltage level, to generate a first shifted input signal to the gate terminal of the first transistor; and
a second level shifter, coupled between the middle node and the gate terminal of the second transistor, configured to receive the first input signal from the middle node and shift the original bias voltage level of the first input signal to a second bias voltage level, to generate a second shifted input signal to the gate terminal of the second transistor; and
the AC signal enhancement circuit comprises:
a first AC signal enhancement circuit, coupled between the gate terminal of the first transistor and the middle node, configured to enhance a first AC signal of the first shifted input signal on the gate terminal of the first transistor according to the voltage difference between the first input signal and the second input signal; and
a second AC signal enhancement circuit, coupled between the gate terminal of the second transistor and the middle node, configured to enhance a second AC signal of the second shifted input signal on the gate terminal of the second transistor according to the voltage difference between the first input signal and the second input signal.

10. The transistor-cascaded circuit of claim 9, wherein the first AC signal enhancement circuit and the second AC signal enhancement circuit comprises a first capacitor and a second capacitor, respectively; in a first phase of a control clock, each of the first capacitor and the second capacitor is configured to sample the voltage difference between the first input signal and the second input signal; and in a second phase of the control clock, the first capacitor is coupled between the gate terminal of the first transistor and the middle node, and the second capacitor is coupled between the gate terminal of the second transistor and the middle node, in order to enhance the first AC signal of the first shifted input signal on the gate terminal of the first transistor and the second AC signal of the second shifted input signal on the gate terminal of the second transistor, respectively.
